(19) United States
(12) Patent Application Publication
(10) Pub. No.: US 2017/0207757 A1
(43) Pub. Date: Jul. 20, 2017

(54) SWITCHED-CAPACITOR CIRCUIT

(71) Applicant: Airoha Technology Corp., Hsinchu (TW)

(72) Inventor: Yu-Hsuan Kang, Hsinchu City (TW)

(21) Appl. No.: 15/405,465

(22) Filed: Jan. 13, 2017

(30) Foreign Application Priority Data
Jan. 15, 2016 (TW) 105101240

(51) Int. Cl. H03F 3/00; H03F 3/45

(52) U.S. Cl. CPC H03F 3/005; H03F 3/45475; H03F 2203/45116

(57) ABSTRACT

A switched-capacitor circuit is provided in the present disclosure. The switched-capacitor circuit includes a first capacitor, a first switch, an amplifier circuit, a second switch, and a second capacitor. The first capacitor includes a first end and a second end. The first switch is coupled between an input end and the first end of the first capacitor. The amplifier circuit includes a first input end, a second input end and an output end. The second switch is coupled between the second end of the first capacitor and the first input end of the amplifier circuit. The second capacitor is coupled between the first capacitor and a ground end. Wherein in a first cycle, the first switch is turned on and the second switch is turned off. And in a second cycle, the first switch is turned off and the second switch is turned on.

This application claims the benefit of Taiwan application Serial No. 105101240, filed Jan. 15, 2016, the subject matter of which is incorporated herein by reference.

### BACKGROUND OF THE INVENTION

Field of the Invention

The invention relates in general to a switched-capacitor circuit.

Description of the Related Art

A switched-capacitor circuit normally includes two switches and a capacitor. The capacitor is coupled between the two switches. The two switches are respectively turned on in two cycles to charge or discharge the capacitor respectively. However, during the switching of the two switches, the MOS switch may generate charge injection. In greater details, when the MOS switch is turned on, there are charges flowing in the channel. At the instant when the MOS switch is turned on or is turned off, charges will flow into the channel or flow out from the channel, and the flow of charges will change the voltages of the nodes at two ends of the MOS switch and cause errors. The charges in the channel of the MOS switch are relevant with VGS. Therefore, if the MOS switch is coupled to an input end, the voltage change at the input end will change the VGS of the MOS switch and generate different charges in the channel. That is, the MOS switch will generate an input-dependent charge injection effect. Since the input-dependent charge injection effect is normally non-linear, total harmonic distortion (THD) may easily turn worse. Therefore, it has become a prominent task for the industries to provide a switched-capacitor circuit capable of eliminating input-dependent charge injection effect.

### SUMMARY OF THE INVENTION

According to an embodiment of the present disclosure, a switched-capacitor circuit is provided. The switched-capacitor circuit includes a first capacitor, a first switch, an amplifier circuit, a second switch and a second capacitor. The first capacitor has a first end and a second end. The first switch is coupled between an input end and the first end of the first capacitor. The amplifier circuit has a first input end, a second input end and an output end. The second switch is coupled between the second end of the first capacitor and the first input end of the amplifier circuit. The second capacitor is coupled between the first capacitor and a ground end. In a first cycle, the first switch is turned on, but the second switch is turned off. In a second cycle, the first switch is turned off, but the second switch is turned on.

The above and other aspects of the invention will become better understood with regard to the following detailed description of the preferred but non-limiting embodiment (s). The following description is made with reference to the accompanying drawings.

### BRIEF DESCRIPTION OF THE DRAWINGS

FIG. 1 shows a circuit diagram of a switched-capacitor circuit according to a first embodiment of the present disclosure.

FIG. 2 shows a circuit diagram of a switched-capacitor circuit according to a second embodiment of the present disclosure.

FIG. 3 shows a circuit diagram of a switched-capacitor circuit according to a third embodiment of the present disclosure.

FIG. 4 shows a circuit diagram of a switched-capacitor circuit according to a fourth embodiment of the present disclosure.

FIG. 5 shows a circuit diagram of a switched-capacitor circuit according to a fifth embodiment of the present disclosure.

### DETAILED DESCRIPTION OF THE INVENTION

FIG. 1 shows a circuit diagram of a switched-capacitor circuit according to a first embodiment of the present disclosure. The switched-capacitor circuit 100 includes a capacitor C1, a switch p1, an amplifier circuit 110, a switch p2 and a capacitor C3. In the present embodiment, the amplifier circuit 110, realized by an integrator circuit, includes an operational amplifier OP1 and a capacitor C2. The capacitor C1 has a first end A and a second end B. The switch p1 is coupled between an input end Vin and the first end A of the capacitor C1 The amplifier circuit has a first input end V−, a second input end V+ and an output end Vout. The switch p2 is coupled between the second end B of the capacitor C1 and the first input end of the amplifier circuit V−. The capacitor C3 is coupled between the capacitor C1 and a ground end. As indicated in FIG. 1, the capacitor C3 is coupled between the second end B of the capacitor C1 and the ground end.

In a first cycle, the first switch p1 is turned on and the second switch p2 is turned off. Meanwhile, the capacitor C1 and the capacitor 03 are charged by an input voltage received from the input end Vin. In a second cycle, the first switch p1 is turned off and the second switch p2 is turned on. The capacitor 03 is discharged and shares the charges to the operational amplifier and the capacitor C2 of the amplifier circuit. In the present example, the impedance of the switch p1 is Ron, the impedance of the capacitor C1 is 1/jωC1, and the impedance of the capacitor C3 is 1/jωC3. The switching frequency of the switches p1 and p2 is several GHz. In the present disclosure, the capacitance of the capacitor C3 can be set as: 1/jωC3<<Ron. Therefore, viewing from the second end B of the capacitor C1, the switch p1 connects the capacitor C1 (whose impedance is Ron+1/jωC1) in series and then connects the capacitor C3 (whose impedance is 1/jωC3<<Ron) in parallel. Under high frequency, the impedance of the capacitor C3 is very small in comparison to that of the switch p1. Therefore, after the capacitor C3 is connected in parallel, the overall impedance viewed from the second end B will be very small, and the charge injection effect caused to the switch p1 by the input end Vin will be greatly eliminated.

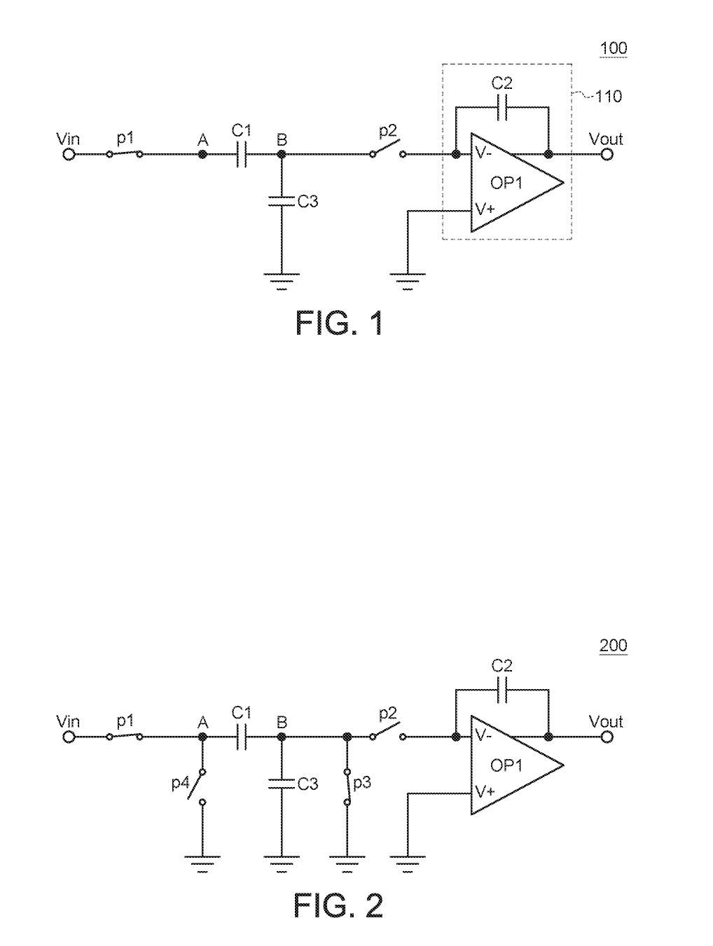

FIG. 2 shows a circuit diagram of a switched-capacitor circuit according to a second embodiment of the present disclosure. In the present embodiment, the switched-capacitor circuit 200 is different from the switched-capacitor circuit 100 of FIG. 1 in that: the switched-capacitor circuit 200 further includes switches p3 and switch p4. The switch p3 is coupled between the second end B of the capacitor C1 and the ground end. The switch p4 is coupled between the first end A of the first capacitor C1 and the ground end. In the present embodiment, the time when the switch p3 being turned on is a period of time earlier than the time when the switch p1 being turned on, and the time when the switch p3 being turned off is a period of time earlier than the time when the switch p1 being turned off. Thus, when the switch p3 is switched to be turned off and the switch p1 is still turned on, the second end B of the capacitor C1 changes to the floating state and cannot keep accumulating charges. Afterwards, when the switch p1 is switched to be turned off, although some residual charges of the switch p1 flow to the first end A of the capacitor C1, the voltage between the two ends A and B of the capacitor C1 still remains unchanged. Therefore, the charge injection effect of the switch p1 will not affect the charges stored in the capacitor C1. Similarly, the time when the switch p4 being turned on is a period of time earlier than the time when the switch p2 being turned on, and the time when the switch p4 being turned off is a period of time earlier than the time hen the switch p2 being turned off. Therefore, the voltage between the two ends A and B of the capacitor C1 also remains unchanged, and will not be affected by the charge injection effect caused to the switch p1 by the input end Vin.

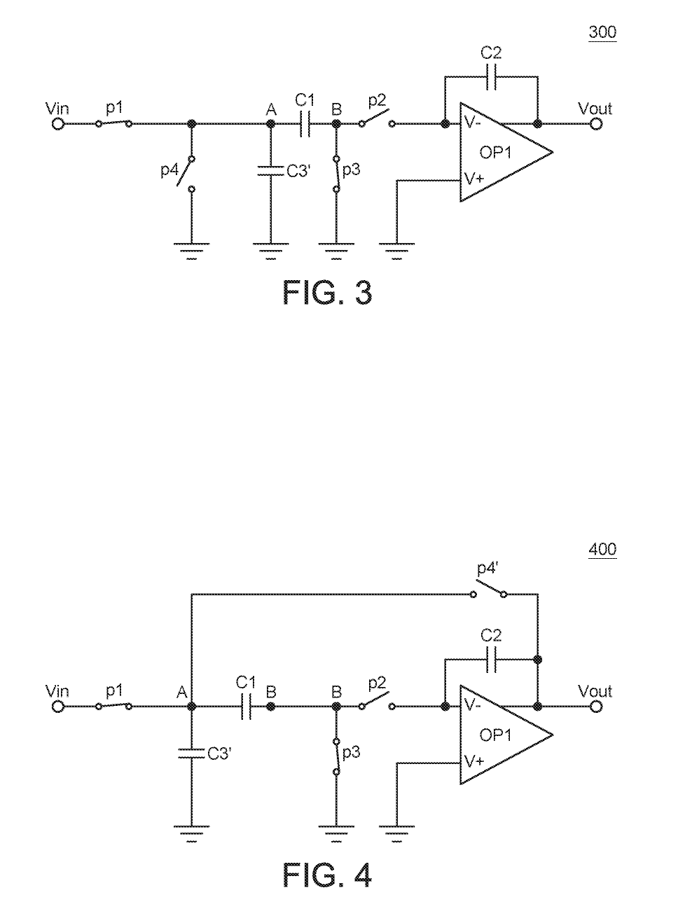

Referring to FIG. 3, a circuit diagram of a switched-capacitor circuit according to a third embodiment of the present disclosure is shown. The switched-capacitor circuit 300 of FIG. 3 is different from the switched-capacitor circuit 200 of FIG. in that: the capacitor C3′ is coupled between the first end A of the capacitor C1 and the ground end. In the present example, viewing from the first end B of the capacitor C1, the switch p1 connects the capacitor C3 in parallel. Under high frequency, the impedance of the capacitor C3 is very small in comparison to that of the switch p1 (1/jωC3<<Ron). Therefore, after the capacitor C3 is connected in parallel, the charge injection effect caused to the switch p1 by the input end Vin will be greatly eliminated.

Referring to FIG. 4, FIG. 4 shows a circuit diagram of a switched-capacitor circuit according to a fourth embodiment of the present disclosure. The switched-capacitor circuit 400 of FIG. 4 is different from the switched-capacitor circuit 300 of FIG. 3 in that: the switch p4′ is coupled between the first end A of the capacitor 01 and the output end Vout. The switched-capacitor circuit 400 of FIG. 4 and the switched-capacitor circuit of above embodiments have similar operations but different circuit structures. Through the design of the switch p1 connecting the capacitor C3′ in parallel, the charge injection effect caused to the switch p1 by the input end Vin can be eliminated. Moreover, through the parallel connection between the switch p4′ and the capacitor C3′, the charge injection effect caused to the switch p4′ by the output end Vout can also be eliminated.

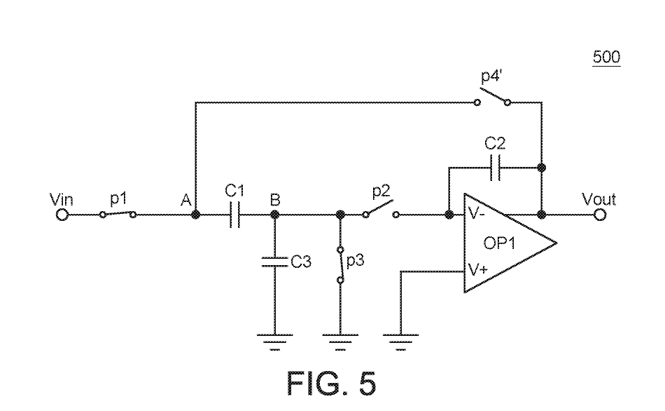

FIG. 5 shows a circuit diagram of a switched-capacitor circuit according to a fifth embodiment of the present disclosure. The switched-capacitor circuit 500 of FIG. 5 is different from the switched-capacitor circuit 400 of FIG. 4 in that: the capacitor C3′ is coupled between the first end A of the capacitor C1 and the ground end. The switched-capacitor circuit 500 of FIG. 5 and the switched-capacitor circuit of above embodiments have similar operations but different circuit structures. Through the design of the switch p1 connecting the capacitor C1 in series and then connecting the capacitor C3 in parallel, the charge injection effect caused to the switch p1 by the input end Vin can be eliminated. Moreover, through the design of the switch p4′ connecting the capacitor C1 in series and then connecting the capacitor C3 in parallel, the charge injection effect caused to the switch p4′ by the output end Vout can also be eliminated.

In above embodiments, the amplifier circuit 110 is realized by an integrator circuit, but the present disclosure is not limited thereto. For example, the amplifier circuit 110 can be realized by other circuit structures, and the types or circuit structures the amplifier circuit are not restricted in the present disclosure.

According to the switched-capacitor circuits disclosed in above embodiments, the charge injection effect caused by the input end or the output end can be eliminated through the design of the switched-capacitor circuit being coupled to a capacitor of a switch capable of generating charge effect and then further connected to another capacitor in parallel.

While the invention has been described by way of example and in terms of the preferred embodiment (s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A switched-capacitor circuit, comprising:
a first capacitor having a first end and a second end;
a first switch coupled between an input end and the first end of the first capacitor;
an amplifier circuit having a first input end, a second input end and an output end;
a second switch coupled between the second end of the first capacitor and the first input end of the amplifier circuit; and
a second capacitor coupled between the first capacitor and a ground end;
wherein in a first cycle, the first switch is turned on and the second switch is turned off; in a second cycle, the first switch is turned off and the second switch is turned on.

2. The switched-capacitor circuit according to claim 1, wherein the second capacitor is coupled between the first end of the first capacitor and the ground end.

3. The switched-capacitor circuit according to claim 1, wherein the second capacitor is coupled between the second end of the first capacitor and the ground end.

4. The switched-capacitor circuit according to claim 1, further comprising:
a third switch coupled between the second end of the first capacitor and the ground end; and
a fourth switch coupled between the firstend of the first capacitor and the ground end.

5. The switched-capacitor circuit according to claim 1, further comprising:
a third switch coupled between the second end of the first capacitor and the ground end; and
a fourth switch coupled between the firstend of the first capacitor and the output end.
